(19) United States
(12) Patent Application Publication
(10) Pub. No.: US 2012/0181691 A1
(43) Pub. Date: Jul. 19, 2012

(54) PACKAGE STRUCTURE, PACKAGING SUBSTRATE AND CHIP

(75) Inventors: Jenq-Gong DUH, Hsinchu (TW); Pen-Shan CHAO, Hsinchu (TW)

(73) Assignee: National Tsing Hua University, Hsinchu (TW)

(21) Appl. No.: 13/167,357

(22) Filed: Jun. 23, 2011

(30) Foreign Application Priority Data
Jan. 13, 2011 (TW) 100101246

(51) Int. Cl. H01L 23/498; H01L 23/48

(52) U.S. Cl. 257/738; 257/769; 257/E23.069; 257/E23.01

(57) ABSTRACT

The present invention relates to a package structure, a packaging substrate and a chip. The package structure includes: a chip including a plurality of electrode pads on a surface thereof; a packaging substrate including a plurality of first conductive pads on a surface thereof; and a plurality of connecting units through which the electrode pads electrically communicate with the first conductive pads, in which the chip or the packaging substrate further includes a first surface finish layer over the electrode pads or the first conductive pads, and the first surface finish layer includes a Ni—Pd alloy layer. Accordingly, the surface finish method applied in a package structure, a packaging substrate and a chip has advantages of simple manufacture, low cost and high reliability.

### CROSS REFERENCE TO RELATED APPLICATION

This application claims the benefits of the Taiwan Patent Application Serial Number 100101246, filed on Jan. 13, 2011, the subject matter of which is incorporated herein by reference.

### BACKGROUND OF THE INVENTION

1. Field of the Invention

The present invention relates to a package structure, a packaging substrate and a chip and, more particularly, to a package structure, a packaging substrate and a chip, which have an easily fabricated and highly reliable surface finish layer.

2. Description of Related Art

As the demands of light, thin, small, and multifunctional electronic products increase and the integrated circuit chip package technology has been developed, the main trends of chip scale package focus on multi-pin package, compact package, fine-pin package and even non-pin package.

In order to satisfy the requirements for miniaturization and high integration, ball grid array package (BGA), chip scale package (CSP) and flip chip package technologies have been the mainstream of package technologies. Thereby, it is an important object for package technologies to meet the demands of reducing volume, increasing I/O connections, enhancing circuit layout density, lowering noise, enhancing reliability of products and reducing cost.

Regarding package technologies, metal surface finishing is one of the major processing methods to enhance reliability of chip and printed circuit package. Commonly used surface finishing technologies in the industry include organic solderability preservatives (OSP), electroless nickel immersion gold (ENIG), and electroless nickel electroless palladium immersion gold (ENEPIG). In ENEPIG, a palladium layer functions as a good barrier layer, which can protect nickel from being corroded and thereby inhibit the formation of black pads. In addition, the deterioration of soldering property caused by diffusion of copper to metal surface can be inhibited in ENEPIG. Thereby, ENEPIG is one of the commonly used metal surface finishing methods.

FIG. 1 shows a cross-sectional view of a packaging substrate treated with ENEPIG. As shown in FIG. 1, a nickel layer 121, a palladium layer 122 and a gold layer 123 are deposited on conductive pads 111 of the packaging substrate 100 in sequence by three electroless plating steps. However, ENEPIG has disadvantages of process complexity and high cost.

### SUMMARY OF THE INVENTION

The object of the present invention is to provide a simple, low cost and highly reliable surface finishing technology, which can be applied in a package structure, a packaging substrate and a chip.

Accordingly, the present invention provides a package structure, including: a chip including a plurality of electrode pads on a first surface thereof; a packaging substrate including a plurality of first conductive pads on a first surface thereof; and a plurality of first connecting units through which the electrode pads electrically communicate with the first conductive pads, in which the chip or the packaging substrate further includes a first surface finish layer disposed over the electrode pads or over the first conductive pads, and the first surface finish layer includes a Ni—Pd alloy layer.

As mentioned above, the present invention uses a single-layered Ni—Pd alloy layer to replace the conventional two-layered structure by a nickel layer and a palladium layer and the single-layered Ni—Pd alloy layer was applied in a surface finish layer of a packaging substrate or/and a chip to obtain the above-mentioned packaging substrate.

Also, the present invention provides a packaging substrate, including: a substrate body including a plurality of first conductive pads on a first surface thereof; and a first surface finish layer disposed over the first conductive pads, which include a Ni—Pd alloy layer. Additionally, the present invention further provides a chip, including: a chip body including a plurality of electrode pads on a first surface thereof; and a first surface finish layer disposed over the electrode pads and the said first surface finish layer includes a Ni—Pd alloy layer.

In comparison with the conventional ENEPIG technology in which a nickel layer and a palladium layer are formed by two electroless plating steps, the present invention uses a single step to form a Ni—Pd alloy layer, and thus has an advantage of simplicity in process. Particularly, in the present invention, the Ni—Pd alloy layer can be formed by electroplating, and thus the manufacturing time can be more significantly reduced in comparison with electroless plating utilized in the conventional ENEPIG technology. Moreover, in addition to the good mechanical properties, the Ni—Pd alloy layer according to the present invention exhibits excellent wettability and a similar contact resistance to those of a gold layer, and thus the step for forming a gold layer can be omitted, further resulting in the reduction of manufacturing cost.

In the present invention, the second surface of the packaging substrate, of which is opposite to the first surface (i.e., the second surface is opposite to the first surface of the substrate body), may further include a plurality of second conductive pads. In particular, a second surface finish layer may be further disposed over the second conductive pads, and the second surface finish layer may also include a Ni—Pd alloy layer. Herein, the second conductive pads may be arranged into a ball grid array to facilitate the subsequent ball grid array package.

In addition, the package structure according to the present invention may further include: a circuit board including a plurality of third conductive pads on a first surface thereof; and a plurality of second connecting units through which the second conductive pads electrically communicate with the third conductive pads.

In the present invention, the package structure is not particularly limited in package type and thus may be any conventional package type. Preferably, the package structure is a flip-chip package structure. Accordingly, the first connecting units are preferably plural first solder bumps, and the second connecting units are plural second solder bumps.

In the present invention, palladium amount in the Ni—Pd alloy layer is preferably less than 5 atom % (atomic percent), and more preferably in the range from 1 atom % (atomic percent) to 3 atom % (atomic percent).

In the present invention, the Ni—Pd alloy layer is not particularly limited in thickness. A person having ordinary knowledge in the art can modify the thickness according to practical requirements. Preferably, the thickness of the Ni—Pd alloy layer ranges from 3 μm to 6 μm.

In the present invention, a person having ordinary knowledge in the art can further form a gold layer over the Ni—Pd alloy layer according to practical requirements. Accordingly, a gold layer may further be disposed over the first surface finish layer and/or over the second surface finish layer.

Furthermore, the present invention further provides a method for fabricating the above-mentioned packaging substrate, including the following steps: providing a substrate body including a plurality of first conductive pads on a first surface thereof; and electroplating a Ni—Pd alloy layer over the first conductive pads as a first surface finish layer.

In the present invention, the substrate body may further include a plurality of second conductive pads on the other surface thereof. Accordingly, the method for fabricating the packaging substrate of the present invention may further include a step: electroplating a Ni—Pd alloy layer over the second conductive pads as a second surface finish layer.

In the present invention, a person having ordinary knowledge in the art can further form a gold layer over the Ni—Pd alloy layer according to practical requirements. Accordingly, the method for fabricating the packaging substrate may further include a step: forming a gold layer over the Ni—Pd alloy layer.

Additionally, the present invention also provides a method for fabricating the above-mentioned chip, including the following steps: providing a chip body including a plurality of electrode pads on a surface thereof; and electroplating a Ni—Pd alloy layer over the electrode pads as a first surface finish layer.

In the present invention, a person having ordinary knowledge in the art can further form a gold layer over the Ni—Pd alloy layer according to practical requirements. Accordingly, the method for fabricating the chip may further include a step: forming a gold layer over the Ni—Pd alloy layer.

Besides, the present invention further provides a method for fabricating a package structure, including the following steps: providing a chip body including a plurality of electrode pads on a first surface thereof and providing a substrate body including a plurality of first conductive pads on a first surface thereof; electroplating a Ni—Pd alloy layer over the electrode pads or the first conductive pads as a first surface finish layer; and forming a plurality of connecting units through which the electrode pads electrically communicate with the first conductive pads.

In the present invention, the substrate body may further include a plurality of second conductive pads on a second surface opposite to the first surface. Accordingly, the method for fabricating the package structure of the present invention may further include a step: electroplating a Ni—Pd alloy layer over the second conductive pads as a second surface finish layer.

In the present invention, a person having ordinary knowledge in the art can further form a gold layer over the Ni—Pd alloy layer according to practical requirements. Accordingly, the method for fabricating the package structure may further include a step: forming a gold layer over the Ni—Pd alloy layer.

In the present invention, the packaging substrate may further include a first solder mask over the first surface thereof (i.e. the first surface of the substrate body), which has a plurality of first openings to expose the first conductive pads. Similarly, the packaging substrate may further include a second solder mask over the second surface thereof (i.e. the second surface of the substrate body), which has a plurality of second openings to expose the second conductive pads.

In the present invention, the chip may further include a passivation layer over the first surface thereof (i.e. the first surface of the chip body), which has a plurality of openings to expose the electrode pads.

In the present invention, an electroplating solution may be used to electroplate the Ni—Pd alloy layer. Specifically, the electroplating solution preferably is a Ni—Pd electroplating solution, in which palladium may range from 18 g/L to 22 g/L (20 g/L is most preferred), nickel may range from 13 g/L to 17 g/L (15 g/L is most preferred), and pH may range from 7.8 to 8.5 (8.0 is most preferred)). Additionally, the electroplating solution may further include an additive, such as Ni—Pd brightener No. 1 (its amount may range from 5 mL/L to 20 mL/L, and 10 mL/L is most preferred), Ni—Pd additive ADD (its amount may range from 15 mL/L to 25 mL/L, and 20 mL/L is most preferred).

In the present invention, the process for electroplating the Ni—Pd alloy layer may be performed under a current density from 0.5 A/dm² to 2.5 A/dm². Preferably, the Ni—Pd alloy layer is formed under a constant current mode.

In the present invention, the time spent on electroplating the Ni—Pd alloy layer depends on the size of the sheet to be electroplated. A person having ordinary knowledge in the art can determine the preferred electroplating time according to Faraday's law. In the present invention, the Ni—Pd alloy layer can be formed by electroplating process at a temperature from 25° C. to 35° C. (preferably at 25° C.).

In the present invention, the Ni—Pd alloy layer can be formed by electroplating process at a pH value from 7.8 to 8.5. In the present invention, the method for forming the gold layer is not particularly limited, and the gold layer may be formed by electroless plating or electroplating.

As mentioned above, in comparison with the conventional ENEPIG technology in which a nickel layer and a palladium layer are formed by two electroless plating steps, the present invention uses a single step to form a Ni—Pd alloy layer, and thus has an advantage of simplicity in process. Particularly, in the present invention, the Ni—Pd alloy layer can be formed by electroplating process, and thus the manufacturing time can be significantly reduced in comparison with electroless plating utilized in the conventional ENEPIG technology. Moreover, in addition to good mechanical properties, the Ni—Pd alloy layer according to the present invention exhibits excellent wettability and a similar contact resistance to that of a gold layer, and thus the step for forming a gold layer can be omitted, further resulting in the reduction of manufacturing cost.

### BRIEF DESCRIPTION OF THE DRAWINGS

FIG. 1 shows a cross-sectional view of a packaging substrate treated with ENEPIG;

FIG. 2 shows a cross-sectional view of a packaging substrate according to one preferred example of the present invention;

FIG. 3 shows a cross-sectional view of a packaging substrate according to another preferred example of the present invention;

FIG. 4 shows a cross-sectional view of a chip according to one preferred example of the present invention;

FIG. 5 shows a cross-sectional view of a chip according to another preferred example of the present invention;

FIG. 6 shows a cross-sectional view of a package structure according to one preferred example of the present invention; and

FIG. 7 shows a cross-sectional view of a package structure according to another preferred example of the present invention.

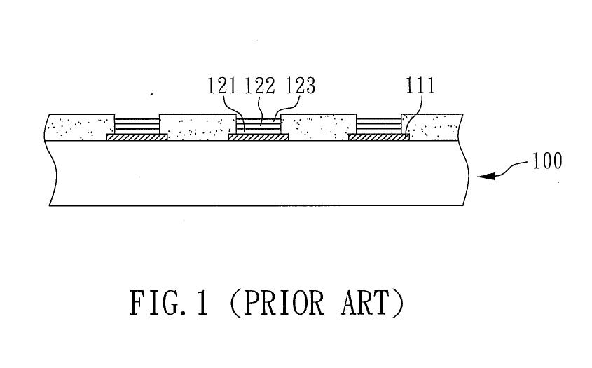

### DETAILED DESCRIPTION OF THE PREFERRED EMBODIMENT

Hereafter, examples will be provided to illustrate the embodiments of the present invention. Other advantages and effects of the invention will become more apparent from the disclosure of the present invention. It should be noted that these accompanying figures are simplified. The quantity, shape and size of components shown in the figures may be modified according to practically conditions, and the arrangement of components may be more complex. Other various aspects also may be practiced or applied in the invention, and various modifications and variations can be made without departing from the spirit of the invention based on various concepts and applications.

### Electroplating Test

A copper sheet or a silicon wafer was used as a sample to be electroplated. In the case of using a silicon wafer as a sample to be electroplated, one or more conductive layers, such as a chromium layer, a titanium layer, a copper layer or a gold layer, must be formed on the surface of the silicon wafer in a single-layered or multi-layered structure as seeding layers. Herein, the present test used a copper sheet manufactured by cold rolling as a sample to be electroplated, and the copper sheet was cut into a size of 2×2 mm so as to make the sequent observation and measurement more easily.

Sand paper No. 4000 was used to remove macroscopic defects on the surface of the copper sheet, such as oxide layers and scars, to enhance the surface flatness and electroplating properties. Subsequently, 1 μm of aluminum oxide sand was used to reduce the surface roughness of the sheet to obtain the luminous surface. Next, the ground and polished sheet was dipped in an acid degreasing fluid at 60-70° C. for 3-5 minutes to remove oil sludge generated from the process of cutting the copper sheet. The dipped copper sheet was washed by deionized water and then dried by nitrogen stream. Subsequently, since the copper sheet is easy to be oxidized, the copper sheet has to be placed into an acid etching liquid to remove oxide layers before performing an electroplating process. Accordingly, the copper sheet was in the order of being dipped in an etching liquid for about 1-3 minutes at room temperature, being washed by deionized water, and being dried by nitrogen stream. Then, the washed copper sheet was placed at a cathode, and a platinized titanium mesh was used as an anode. The cathode and anode were placed into an electroplating bath, and the distance between the cathode and the anode was adjusted to be within 10-20 cm. Accordingly, a Ni—Pd alloy layer was formed by electroplating at 25° C. with a current density of about 1 A/dm². Finally, the sheet was washed by deionized water and then dried by nitrogen stream.

A surface profiler was used to measure the thickness of the Ni—Pd alloy layer (about 5.06 um). Also, a person having ordinary knowledge in the art can form a Ni—Pd alloy layer of various thickness (e.g. 3-6 um) by modifying the electroplating time. In addition, a field emission electron probe X-ray Micro analyzer (FE-EPMA) was used to analyze the amount of palladium in the Ni—Pd alloy layer. The table 1 below shows the amount of palladium in the Ni—Pd alloy layer manufactured under different electroplating conditions.

TABLE 1

| Sheet | | A | B | C |
|---|---|---|---|---|
| Electroplating | Pd | 18 | 20 | 22 |
| Bath | Ni | 17 | 15 | 13 |
| | Ni—Pd brightener No. 1 | 10 | 10 | 10 |
| | Ni—Pd additive ADD | 20 | 20 | 20 |
| | pH value | 8 | 8 | 8 |

| | | | |
|---|---|---|---|
| Amount of Pd (atom %) | 1 | 3 | 5 |

### Example 1

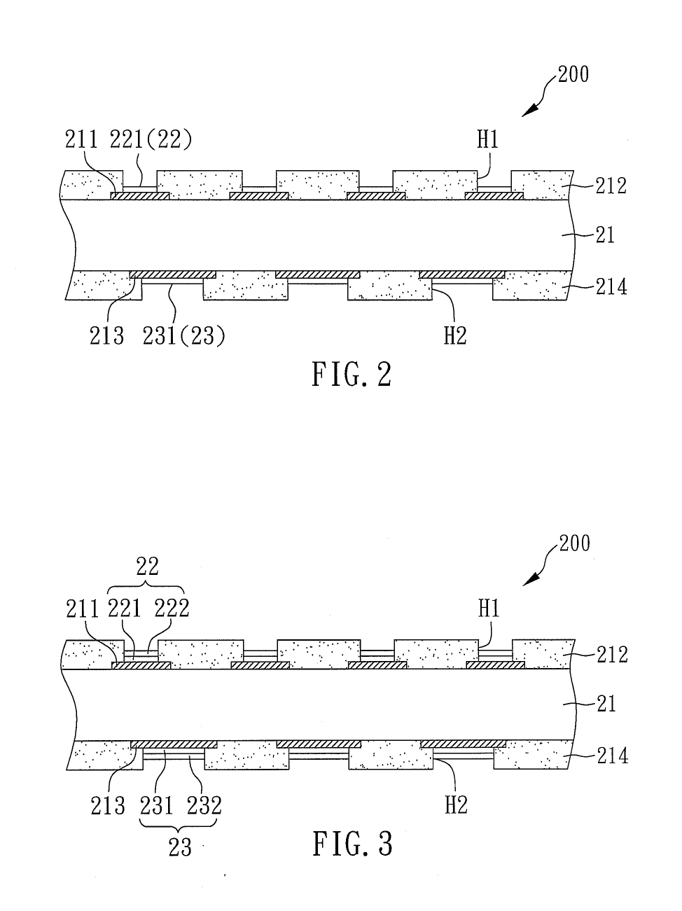

FIG. 2 shows a cross-sectional view of a packaging substrate 200 according to one preferred example of the present invention.

As shown in FIG. 2, a substrate body 21, including a plurality of first conductive pads 211 and a first solder mask 212 on a first surface thereof and a plurality of second conductive pads 213 and a second solder mask 214 on a second surface (opposite to the first surface) thereof, was provided. Herein, the first solder mask 212 and the second solder mask 214 have a plurality of first openings H1 and second openings H2 to expose the first conductive pads 211 and second conductive pads 213, respectively. Subsequently, the first conductive pads 211 in the first openings H1 and the second conductive pads 213 in the second openings H2 were provided with a Ni—Pd alloy layer 221, 231 in thickness of about 5.06 μm thereon by electroplating as a first surface finish layer 22 and a second surface finish layer 23, respectively. Herein, the second conductive pads 213 were arranged into a ball grid array.

In detail, the process for electroplating the Ni—Pd alloy layer 221, 231 according to the present example is illustrated as follows. The substrate body 21 was placed at a cathode, and a platinized titanium net was used as an anode. The cathode and anode were placed into an electroplating bath, and the distance between the cathode and the anode was adjusted to 10-20 cm. Accordingly, a Ni—Pd alloy layer was formed by electroplating under a current density of about 1 A/dm² at 25° C. Herein, the electroplating conditions as shown in the sheet A of Table 1 was applied in the present example. Finally, the packaging substrate 200 by the electroplating process was washed by deionized water and dried by nitrogen steam. Accordingly, the Ni—Pd alloy layer 221, 231 formed by the present example contains palladium in an amount of about 1 atom %.

Thereby, as shown in FIG. 2, the present example provide a packaging substrate 200, including: a substrate body 21 including a plurality of first conductive pads 211 on a first surface thereof and a plurality of second conductive pads 213 on a second surface thereof; and a first surface finish layer 22 and a second surface finish layer 23, disposed on the first conductive pads 211 and the second conductive pads 213, respectively, therewith each of the first surface finish layer 22 and the second surface finish layer 23 including a Ni—Pd alloy layers 221, 231.

### Example 2

FIG. 3 shows a cross-sectional view of a packaging substrate 200 according to another preferred example of the present invention.

As shown in FIG. 3, a substrate body 21, including a plurality of first conductive pads 211 and a first solder mask 212 on a first surface thereof and a plurality of second conductive pads 213 and a second solder mask 214 on a second surface (opposite to the first surface) thereof, was provided. Herein, the first solder mask 212 and the second solder mask 214 have a plurality of first openings H1 and second openings H2 to expose the first conductive pads 211 and second conductive pads 213, respectively.

Subsequently, the first conductive pads 211 in the first openings H1 and the second conductive pads 213 in the second openings H2 were provided with a Ni—Pd alloy layer 221, 231 in thickness of about 5.06 μm and a gold layer 222, 232 in thickness of about 0.02 μm thereon by electroplating as a first surface finish layer 22 and a second surface finish layer 23, respectively. Herein, the second conductive pads 213 were arranged into a ball grid array.

In detail, the process for electroplating the Ni—Pd alloy layer 221, 231 according to the present example is illustrated as follows. The substrate body 21 was placed at a cathode, and a platinized titanium net was used as an anode. The cathode and anode were placed into an electroplating bath, and the distance between the cathode and the anode was adjusted to 10-20 cm. Accordingly, a Ni—Pd alloy layer was formed by electroplating under a current density of about 1 A/dm² at 25° C. Herein, the electroplating conditions as shown in the sheet B of Table 1 was applied in the present example. Finally, the packaging substrate 200 by the electroplating process was washed by deionized water and dried by nitrogen steam. Accordingly, the Ni—Pd alloy layer 221, 231 formed by the present example contains palladium in an amount of about 3 atom %.

Thereby, as shown in FIG. 3, the present example provide a packaging substrate 200, including: a substrate body 21 including a plurality of first conductive pads 211 on a first surface thereof and a plurality of second conductive pads 213 on a second surface thereof; and a first surface finish layer 22 and a second surface finish layer 23, disposed on the first conductive pads 211 and the second conductive pads 213, respectively, therewith each of the first surface finish layer 22 and the second surface finish layer 23 including a Ni—Pd alloy layers 221, 231, and a gold layer 222, 232 disposed on the Ni—Pd alloy layer 221, 231.

### Example 3

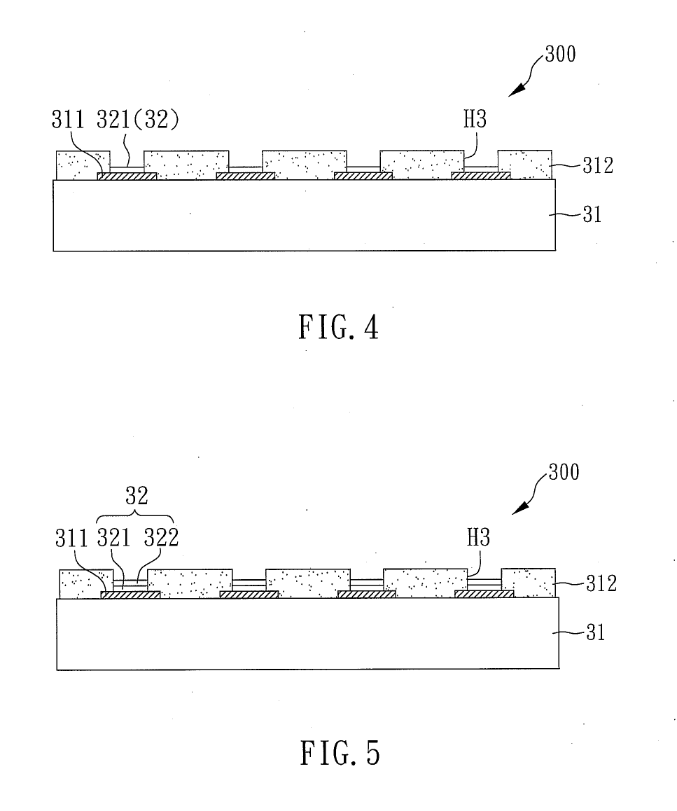

FIG. 4 shows a cross-sectional view of a chip 300 according to one preferred example of the present invention.

As shown in FIG. 4, a chip body 31, including a plurality of electrode pads 311 and a passivation layer 312 on a first surface thereof, was provided. Herein, the passivation layer 312 has a plurality of openings H3 to expose the electrode pads 311. Subsequently, the electrode pads 211 in the openings H3 were provided with a Ni—Pd alloy layer 321 in thickness of about 5.06 μm thereon by electroplating as a first surface finish layer 32.

In detail, the process for electroplating the Ni—Pd alloy layer 321 according to the present example is illustrated as follows. The chip 31 was placed at a cathode, and a platinized titanium net was used as an anode. The cathode and anode were placed into an electroplating bath, and the distance between the cathode and the anode was adjusted to 10-20 cm. Accordingly, a Ni—Pd alloy layer was formed by electroplating under a current density of about 1 A/dm² at 25° C. Herein, the electroplating conditions as shown in the sheet A of Table 1 was applied in the present example. Finally, the chip 300 by the electroplating process was washed by deionized water and dried by nitrogen steam. Accordingly, the Ni—Pd alloy layer 321 formed by the present example contains palladium in an amount of about 1 atom %.

Thereby, as shown in FIG. 4, the present example provide a chip 300, including: a chip body 31 including a plurality of electrode pads 311 on a first surface thereof; and a first surface finish layer 32 disposed on the electrode pads 311 and including a Ni—Pd alloy layers 321.

### Example 4

FIG. 5 shows a cross-sectional view of a chip 300 according to another preferred example of the present invention.

As shown in FIG. 5, a chip body 31, including a plurality of electrode pads 311 and a passivation layer 312 on a first surface thereof, was provided. Herein, the passivation layer 312 has a plurality of openings H3 to expose the electrode pads 311. Subsequently, the electrode pads 211 in the openings H3 were provided by electroplating in the order with a Ni—Pd alloy layer 321 in thickness of about 5.06 μm and a gold layer 322 in thickness of about 0.02 μm thereon as a first surface finish layer 32.

In detail, the process for electroplating the Ni—Pd alloy layer 321 according to the present example is illustrated as follows. The chip 31 was placed at a cathode, and a platinized titanium net was used as an anode. The cathode and anode were placed into an electroplating bath, and the distance between the cathode and the anode was adjusted to 10-20 cm. Accordingly, a Ni—Pd alloy layer was formed by electroplating under a current density of about 1 A/dm² at 25° C. Herein, the electroplating conditions as shown in the sheet C of Table 1 was applied in the present example. Finally, the chip 300 by the electroplating process was washed by deionized water and dried by nitrogen steam. Accordingly, the Ni—Pd alloy layer 321 formed by the present example contains palladium in an amount of about 5 atom %.

Thereby, as shown in FIG. 5, the present example provided a chip 300, including: a chip body 31 including a plurality of electrode pads 311 on a first surface thereof; and a first surface finish layer 32 disposed on the electrode pads 311 and including a Ni—Pd alloy layers 321 and a gold layer 322, therewith the gold layer 322 being disposed on the Ni—Pd alloy layers 321.

### Example 5

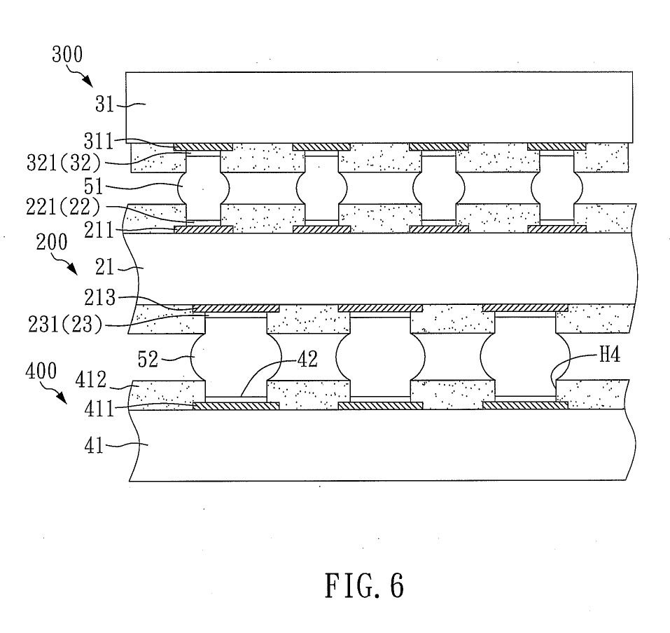

FIG. 6 shows a cross-sectional view of a package structure according to one preferred example of the present invention.

As shown in FIG. 6, the chip 300 prepared by Example 3 was attached to the packaging substrate 200 prepared by Example 1 via a plurality of first connecting units 51 in a flip-chip manner. In detail, the electrode pads 311 of the chip 300 electrically communicate with the first conductive pads 211 of the packaging substrate 200 via the first connecting units 51. In addition, the second conductive pads 213 of the packaging substrate 200 electrically communicate with the third conductive pads 411 of the circuit board 400 via the second connecting units 52. Herein, the circuit board 400 includes: a circuit board body 41 including a plurality of third conductive pads 411 and a solder mask 412 on a first surface thereof, therewith the solder mask 412 having a plurality of openings H4 to expose the third conductive pags 411; and a third surface finish layer 42 disposed on the third conductive pads 411. In the present example, the third surface finish layer 42 of the circuit board 400 is an organic solderability preservative layer.

Thereby, as shown in FIG. 6, the present example provide a package structure, including: a chip 300 including a plurality of electrode pads 311 on a first surface thereof; a packaging substrate 200 including a plurality of first conductive pads 211 on a first surface thereof and a plurality of second conductive pads 213 on a second surface thereof; a plurality of first connecting units 51 through which the electrode pads 311 electrically communicate with the first conductive pads 211; a circuit board 400 including a plurality of third conductive pads 411 on a first surface thereof; and a plurality of second connecting units 52 through which the second conductive pads 213 electrically communicate the third conductive pads 411. Herein, the packaging substrate 200 further includes a first surface finish layer 22 and a second surface finish layer 23 disposed on the first conductive pads 211 and the second conductive pads 213, respectively; the chip 300 further includes a first surface finish layer 32 disposed on the electrode pads 311; and the circuit board 400 further includes a third surface finish layer 42 disposed on the third conductive pads 411. In the present example, the first surface finish layer 22, 32 and the second surface finish layer 23 each include a Ni—Pd alloy layer 221, 231, 321.

### Example 6

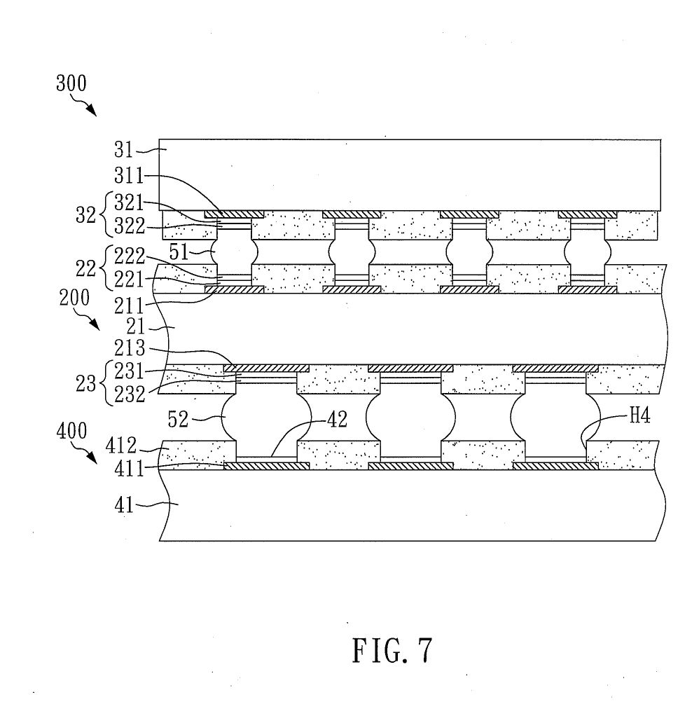

FIG. 7 shows a cross-sectional view of a package structure according to another preferred example of the present invention.

As shown in FIG. 7, the chip 300 prepared by Example 4 was attached to the packaging substrate 200 prepared by Example 2 via a plurality of first connecting units 51 in a flip-chip manner. In detail, the electrode pads 311 of the chip 300 electrically communicate with the first conductive pads 211 of the packaging substrate 200 via the first connecting units 51. In addition, the second conductive pads 213 of the packaging substrate 200 electrically communicate with the third conductive pads 411 of the circuit board 400 via a plurality of second connecting units 52. Herein, the circuit board 400 includes:

a circuit board body 41 including a plurality of third conductive pads 411 and a solder mask 412 on a first surface thereof, therewith the solder mask 412 having a plurality of openings H4 to expose the third conductive pads 411; and a third surface finish layer 42 disposed on the third conductive pads 411. In the present example, the third surface finish layer 42 of the circuit board 400 is an organic solderability preservative layer.

Thereby, as shown in FIG. 7, the present example provide a package structure, including: a chip 300 including a plurality of electrode pads 311 on a first surface thereof; a packaging substrate 200 including a plurality of first conductive pads 211 on a first surface thereof and a plurality of second conductive pads 213 on a second surface thereof; a plurality of first connecting units 51 through which the electrode pads 311 electrically communicate with the first conductive pads 211; a circuit board 400 including a plurality of third conductive pads 411 on a first surface thereof; and a plurality of second connecting units 52 through which the second conductive pads 213 electrically communicate the third conductive pads 411. Herein, the packaging substrate 200 further includes a first surface finish layer 22 and a second surface finish layer 23 disposed on the first conductive pads 211 and the second conductive pads 213, respectively; the chip 300 further includes a first surface finish layer 32 disposed on the electrode pads 311; and the circuit board 400 further includes a third surface finish layer 42 disposed on the third conductive pads 411. In the present example, the first surface finish layer 22, 32 and the second surface finish layer each include a Ni—Pd alloy layer 221, 231, 321 and a gold layer 222, 232, 322.

The above examples are intended for illustrating the embodiments of the subject invention and the technical features thereof, but not for restricting the scope of protection of the subject invention. The scope of the subject invention is based on the claims as appended.

What is claimed is:

1. A package structure, comprising:
a chip comprising a plurality of electrode pads on a first surface thereof;
a packaging substrate comprising a plurality of first conductive pads on a first surface thereof; and
a plurality of first connecting units through which the electrode pads electrically communicate with the first conductive pads, wherein the chip or the packaging substrate further comprises a first surface finish layer over the electrode pads or the first conductive pads, and the first surface finish layer comprises a Ni—Pd alloy layer.

2. The package structure as claimed in claim 1, wherein the Ni—Pd alloy layer contains palladium in an amount of 5 atom % or less.

3. The package structure as claimed in claim 2, wherein the Ni—Pd alloy layer contains palladium in an amount from 1 atom % to 3 atom %.

4. The package structure as claimed in claim 1, wherein the Ni—Pd alloy layer ranges from 3 μm to 6 μm in thickness.

5. The package structure as claimed in claim 1, wherein the Ni—Pd alloy layer is formed by electroplating.

6. The package structure as claimed in claim 1, wherein the packaging substrate further comprises a plurality of second conductive pads on a second surface thereof opposite to the first surface.

7. The package structure as claimed in claim 6, wherein the packaging substrate further comprises a second surface finish layer over the second conductive pads, and the second surface finish layer comprises a Ni—Pd alloy layer.

8. The package structure as claimed in claim 6, further comprising: a circuit board comprising a plurality of third conductive pads on a first surface thereof; and a plurality of second connecting units through which the second conductive pads electrically communicate with the third conductive pads.

9. The package structure as claimed in claim 1, wherein the first surface finish layer further comprises a gold layer over the Ni—Pd alloy layer.

10. The package structure as claimed in claim 7, wherein the first surface finish layer or the second surface finish layer further comprises a gold layer over the Ni—Pd alloy layer.

11. The package structure as claimed in claim 1, wherein the package structure is a flip-chip package structure, and the first connecting units are plural solder bumps.

12. The package structure as claimed in claim 6, wherein the second conductive pads are arranged in a ball grid array.

13. A chip, comprising:
a chip body comprising a plurality of electrode pads on a first surface thereof; and
a first surface finish layer disposed over the electrode pads and comprising a Ni—Pd alloy layer.

14. The chip as claimed in claim 13, wherein the Ni—Pd alloy layer contains palladium in an amount of 5 atom % or less.

15. The chip as claimed in claim 14, wherein the Ni—Pd alloy layer contains palladium in an amount from 1 atom % to 3 atom %.

16. The chip as claimed in claim 13, wherein the Ni—Pd alloy layer ranges from 3 μm to 6 μm in thickness.

17. The chip as claimed in claim 13, wherein the Ni—Pd alloy layer is formed by electroplating.

18. The chip as claimed in claim 13, wherein the first surface finish layer further comprises a gold layer over the Ni—Pd alloy layer.

19. A packaging substrate, comprising:
a substrate body comprising a plurality of first conductive pads on a first surface thereof; and
a first surface finish layer, disposed over the first conductive pads and comprising a Ni—Pd alloy layer.

20. The packaging substrate as claimed in claim 19, wherein the Ni—Pd alloy layer contains palladium in an amount of 5 atom % or less.

21. The packaging substrate as claimed in claim 20, wherein the Ni—Pd alloy layer contains palladium in an amount from 1 atom % to 3 atom %.

22. The packaging substrate as claimed in claim 19, wherein the Ni—Pd alloy layer ranges from 3 μm to 6 μm in thickness.

23. The packaging substrate as claimed in claim 19, wherein the Ni—Pd alloy layer is formed by electroplating.

24. The packaging substrate as claimed in claim 19, wherein the substrate body further comprising a plurality of second conductive pads on a second surface thereof opposite to the first surface.

25. The packaging substrate as claimed in claim 24, further comprising a second surface finish layer disposed over the second conductive pads, wherein the second surface finish layer comprises a Ni—Pd alloy layer.

26. The packaging substrate as claimed in claim 19, wherein the first surface finish layer further comprises a gold layer over the Ni—Pd alloy layer.

27. The packaging substrate as claimed in claim 25, wherein the first surface finish layer or the second surface finish layer further comprises a gold layer over the Ni—Pd alloy layer.
